(19) United States
(12) Patent Application Publication
(10) Pub. No.: US 2009/0085044 A1
(43) Pub. Date: Apr. 2, 2009

(54) SILICON CARBIDE SEMICONDUCTOR SUBSTRATE AND SILICON CARBIDE SEMICONDUCTOR DEVICE BY USING THEREOF

(76) Inventors: Toshiyuki Ohno, Kokubunji (JP); Natsuki Yokoyama, Mitaka (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 12/195,039

(22) Filed: Aug. 20, 2008

(30) Foreign Application Priority Data
Sep. 28, 2007 (JP) 2007-255682

(51) Int. Cl. H01L 29/24

(52) U.S. Cl. 257/77; 257/E29.104

(57) ABSTRACT

A manufacturing method is provided for a silicon carbide semiconductor substrate adapted for reduced basal plane dislocations in a silicon carbide epitaxial layer. Between a silicon carbide epitaxial layer for device fabrication (i.e., a drift layer) and a base substrate formed of a silicon carbide single-crystal wafer, a highly efficient dislocation conversion layer through which any basal plane dislocations in the silicon carbide single-crystal wafer are converted into threading edge dislocations very efficiently when the dislocations propagate into the layer epitaxially grown is provided by epitaxial growth. Assigning to the dislocation conversion layer a donor concentration lower than that of the drift layer, therefore, allows the above conversion of a larger number of basal plane dislocations than the case where the drift layer exists alone (without the dislocation conversion layer).

### CLAIM OF PRIORITY

The present application claims priority from Japanese patent application JP 2007-255682 filed on Sep. 28, 2007, the content of which is hereby incorporated by reference into this application.

### BACKGROUND OF THE INVENTION

1. Field of the Invention

The present invention relates to a silicon carbide semiconductor substrate and a silicon carbide semiconductor device formed on the same.

2. Description of the Related Art

Silicon carbide (SiC), compared with silicon (Si), has a large bandgap and high breakdown field, so the application of silicon carbide to the next generation of semiconductor devices (power devices) for electric power control is anticipated. Silicon carbide is known to exhibit various crystal structures, which include the hexagonal 4H—SiC and 6H—SiC used to create practical power devices.

Since a large portion of power devices need to supply a large current throughout their own internal circuits, these semiconductor devices are each constructed to have an independent electrode on the surface and reverse side each of the device so that a major current flows between both electrodes. The power device also requires a function that realizes an on-state, the state where the major current is supplied, and an off-state, the state where the major current is cut off. In the on-state, resistance that occurs in the supply current, that is, on-resistance needs to be lower for reducing electrical device loss, and in the off-state, the device is required to minimize current leakage relative to the applied voltage.

In order to implement such silicon carbide-based power device functionality as described above, a general silicon carbide power device uses a low-resistance silicon carbide single-crystal wafer as a base substrate, and includes a silicon carbide layer of a single crystal, the silicon carbide layer being formed on the wafer by epitaxy to possess desired thickness and a desired donor concentration. Basic semiconductor device structures including a p-n junction are built into the silicon carbide epitaxial layer. The design for these devices is optimized for the epitaxial layer to be high in resistance, for the thickness and donor concentration of this layer to satisfy a withstand voltage value that is one of the specifications of the device, and for on-resistance to be minimized. During device forming in this manner, the epitaxial layer provided on the silicon carbide single-crystal wafer is used because the high-resistance silicon carbide layer whose thickness ranges from about several micrometers to about several tens of micrometers is about one-tenth as great as the high-resistance layer required for a conventional device based on silicon.

During the development of a silicon carbide single-crystal wafer with conventional technology, the surface of the wafer has needed forming to include a {0001} crystal plane in order to obtain a larger wafer diameter and a longer wafer ingot. Traditionally, it has been a problem that during epitaxial growth of a silicon carbide single-crystal layer on the {0001} crystal plane, another crystal type (polytype) of silicon carbide different from that of the wafer is created in mixed form. Inclining the epitaxial-layer growth wafer surface by several degrees from the {0001} crystal plane, however, has made it possible to solve the above problem and thus to easily form the same polytype of silicon carbide single-crystal layer as that of the wafer. The surfaces of the 4H—SiC wafers currently available on the market have the respective {0001} crystal planes inclined by 4 or 8 degrees.

Along with the development of larger-diameter wafers, attempts to improve the quality of silicon carbide single-crystal wafers are being energetically advanced. Even nowadays, however, crystallographic structural defects called “dislocations” exist at the rate of 1,000 to 10,000 pieces per square centimeter in silicon carbide single-crystal wafers. The dislocations in silicon carbide are classified into three types: threading screw dislocations, threading edge dislocations, and basal plane dislocations. In the first two kinds of dislocations, the direction of the dislocation line is nearly perpendicular to the {0001} crystal plane, and in the last kind of dislocation, the direction of the dislocation line is parallel to the {0001} crystal plane.

If one end of the dislocation line is exposed on the surface of the wafer, these dislocations are inherited to the silicon carbide single-crystal layer epitaxially grown on the wafer. If the surface of the wafer is parallel to the {0001} crystal plane, basal plane dislocations are not inherited to the layer epitaxially grown. If the {0001} crystal plane is inclined, however, part of the basal plane dislocations on this plane, as discussed above, are exposed on the wafer surface, in which case, the particular basal plane dislocations propagate to the layer epitaxially grown. In the latter case, according to the Journal of Crystal Growth, Vol. 260, pp. 209-216, although many of the basal plane dislocations which have propagated change the directions of the respective dislocation lines and become threading edge dislocations in the epitaxially grown layer, about 10 to 20 percent of the basal plane dislocations exposed on the wafer surface are inherited intact as basal plane dislocations to the epitaxially grown layer. It is also described in the above publication that conversely, the threading edge dislocations exposed on the wafer surface are substantially 100% propagate in the form of threading edge dislocations into the epitaxially grown layer and substantially no threading edge dislocations change into basal plane dislocations.

Research is proceeding to analyze what kinds of impacts the dislocations in epitaxially grown silicon carbide have upon the performance and reliability of the device. Not all impacts are elucidated yet, but it is already made clear that when a current is supplied to a p-n junction diode over a long time, the basal plane dislocations in the epitaxial layer increase on-resistance. The basal plane dislocations also deteriorate the reliability of a gate oxide film in a metal-oxide semiconductor field-effect transistor (MOSFET). Meanwhile, impacts of threading screw dislocations and threading edge dislocations upon the device are not definitely admitted. It is desirable, therefore, that the epitaxial layer into which various structures of the device are built should have the smallest possible number of basal plane dislocations, and if possible, none. To this end, the basal plane dislocation density in the silicon carbide single-crystal wafer to be used as a substrate should be significantly reducible, but there are still no prospects for the reduction in the dislocation density. Accordingly, it is becoming a vital technique how to reduce the relative ratio of the basal plane dislocations exposed on the surface of the silicon carbide single-crystal wafer, with respect to the basal plane dislocations that are inherited intact as basal plane dislocations to the epitaxially grown layer when propagating thereinto, that is, stated differently, how to enhance conversion efficiency at which the basal plane dislocations in the wafer are converted into threading edge dislocations when propagating into the epitaxially grown layer.

JP-A-2003-318388 discloses a technique in which an epitaxial layer higher than a drift layer in donor concentration is provided between the drift layer, which is the silicon carbide epitaxial layer with a device built thereinto, and a base substrate, but this technique is proposed from a viewpoint different from the above. The association of this technique with respect to the present invention will be described later herein.

### SUMMARY OF THE INVENTION

Methods for reducing the basal plane dislocation density in an epitaxial layer by enhancing the conversion efficiency at which the basal plane dislocations in the wafer are converted into threading edge dislocations include the method disclosed in, for example, JP-T-2007-506289. In the method of JP-T-2007-506289, a section with exposed basal plane dislocations on the surface of a silicon carbide single-crystal wafer is selectively etched to form a concave portion that primarily includes dislocations, and to thereby grow an epitaxial layer on the wafer. In the thus-formed epitaxial layer, as described in Materials Science Forum, Vols. 527-529, pp. 243-246, the basal plane dislocations are significantly reduced. However, as described in Materials Science Forum, Vols. 527-529, pp. 1329-1334, whereas the reliability of the on-state characteristics of a p-n junction built into such an epitaxial layer is surely improved by a decrease in basal plane dislocation density, the off-state characteristics of the p-n junction are conversely deteriorated by the decrease. This is probably because the growth of the epitaxial layer on the concave wafer has caused other crystal defects around the concave portion. The method in which the section on a silicon carbide single-crystal wafer surface where exposed basal plane dislocations exist is selectively etched to form a concave portion on the surface and grow an epitaxial layer on the wafer is effective for reducing the basal plane dislocation density. On the whole, however, this method is not suitable for forming an epitaxial layer into which to build a semiconductor device. What is needed is means for reducing the basal plane dislocation density in an epitaxial layer without affecting the film quality of the epitaxial layer in any forms.

The present invention provides a method of manufacturing a silicon carbide semiconductor substrate whose basal plane dislocation density in an epitaxial layer can be reduced without adversely affecting film quality of the epitaxial layer in any forms. In this method, a dislocation conversion layer in which any basal plane dislocations in a silicon carbide single-crystal wafer are converted into threading edge dislocations very efficiently during propagation into the layer epitaxially grown is provided between a drift layer and a base substrate by epitaxy. In this case, the drift layer is the silicon carbide epitaxial layer with a device built thereinto, and the base substrate is formed of the silicon carbide single-crystal wafer. Through fundamental experiments, the present inventors obtained the following knowledge on conditions for forming the dislocation conversion layer: if the base substrate is a low-resistance n-type silicon carbide single-crystal wafer, a rate at which the basal plane dislocations in the wafer are converted into threading edge dislocations during propagation into the layer epitaxially grown increase as a donor concentration in the epitaxial layer decreases.

Therefore, the epitaxial layer needs forming under the conditions that minimize the donor concentration. The donor concentration in the epitaxial layer adopted as the drift layer, however, cannot be determined by mere reasoning only for reducing the dislocation density. This is because, as discussed earlier herein, the donor concentration in the drift layer is a quantity that requires optimization during the withstand voltage design for the device. Accordingly, in the present invention, a thin epitaxial layer of a low donor concentration for implementing highly efficient conversion of the basal plane dislocations into threading edge dislocations is provided as the dislocation conversion layer between the substrate and the drift layer. The donor concentration in the dislocation conversion layer is determined independently of that of the drift layer, and hence, appropriately determined to obtain a higher basal-plane dislocation conversion ratio without affecting the concentration determining the specification of the device. If a donor concentration higher than that of the drift layer is assigned to the dislocation conversion layer, there is no meaning in specially providing this layer, for the conversion of dislocations at the drift layer suffices in that case. A donor concentration lower than that of the drift layer is therefore assigned to the dislocation conversion layer. This allows the conversion of a larger number of basal plane dislocations than if the drift layer is present alone (without the dislocation conversion layer). Basal plane dislocations that have been converted into threading edge dislocations by the dislocation conversion layer do not return to the respective original basal-plane dislocation formed at an interface between the dislocation conversion layer and the drift layer. Consequently, providing the dislocation conversion layer allows the basal plane dislocation density in the drift layer to be made smaller than the case where the drift layer is present alone. These properties are shown when assigning to the dislocation conversion layer a donor concentration level lower than that of the drift layer correspondingly increases effectiveness of the present invention. The donor concentration in the drift layer is usually designed to range from an order of 10¹⁵ cm⁻³ to an order of 10¹⁶ cm⁻³, so the donor concentration in the dislocation conversion layer is desirably set to be 10¹⁵ cm⁻³ or less. Additionally, according to the experiments of the present inventors, reducing the donor concentration in the dislocation conversion layer to a level of about 1×10 ¹⁴ cm⁻³, it is estimated that a propagation ratio of the basal plane dislocations is reduced to substantially 0, that is, the conversion ratio of the basal plane dislocations is reduced to substantially 1. Significant reduction of the propagation of the basal plane dislocations into the drift layer is therefore anticipated.

Thickness of the dislocation conversion layer can also be determined independently of that of the drift layer. The conversion of the basal plane dislocations into threading edge dislocations, however, is an event occurring in a region slightly inside the dislocation conversion layer from an interface between the substrate and the dislocation conversion layer. Increasing the thickness of the dislocation conversion layer, therefore, has no meaning to the conversion of the dislocations. Rather, thickening the dislocation conversion layer could result in the on-resistance of the device being enhanced. It is desirable, therefore, that the dislocation conversion layer be thinner.

The silicon carbide is epitaxially grown to form the dislocation conversion layer. In this meaning, although the growth conditions differ from those of the drift layer, the forming method itself is the same. This makes it easy to form continuously the dislocation conversion layer and the drift layer by, for example, forming the dislocation conversion layer under desired conditions first, and then after a lapse of a desired time, by changing the growth conditions such as a flow rate of a source gas which controls the donor concentration, and forming the drift layer. Providing the dislocation conversion layer, therefore, does not cause new defects in the drift layer.

The basal plane dislocations are converted into threading edge dislocations more efficiently as the donor concentration in the epitaxial layer decreases. The reason is considered as described below. Nitrogen that is used as the donor is replaced by carbon in a crystal lattice of the silicon carbide. At this time, the crystal lattice of the silicon carbide is reduced in size with an increase in the donor concentration, since nitrogen has a covalent radius smaller than that of carbon. The silicon carbide semiconductor wafer used as the base substrate of the epitaxial layer for a silicon carbide power device is usually of a low-resistance n-type, containing nitrogen as the donor at a concentration level of at least 1×10¹⁸ cm⁻³. The donor concentration in the epitaxial layer, ranging from an order of 10¹⁴ cm⁻³ to an order of 10¹⁷ cm⁻³, is lower than the donor concentration of the base substrate, so the reduction or low ratio in size of the crystal lattice in the epitaxial layer is not as great as that in the base substrate. However, since the epitaxial layer is grown under a firm-contact state with respect to the surface of the base substrate, it is considered that the crystal lattice near the interface to the base substrate in the epitaxial layer cannot maintain an original lattice size and is compressively stressed by the crystal lattice of the base substrate that has been dimensionally reduced in comparison with the crystal lattice of the epitaxial layer. That is to say, the crystal lattice in the epitaxial layer, near the interface to the base substrate, is distorted because of the base substrate being present there. It is considered that as the difference between the donor concentration of the base substrate and that of the epitaxial layer increases, the crystal lattice in the epitaxial layer, near the interface to the base substrate, is distorted more significantly by the presence of the crystal lattice in the base substrate, and hence that the distortion makes the basal plane dislocations more easily convertible into threading edge dislocations.

In the present invention, the epitaxial layer with a donor concentration lower than that of the drift layer is provided between the drift layer and the base substrate, but as disclosed in JP-A-2003-318388, there is a technique in which an epitaxial layer with a donor concentration higher than that of a drift layer is provided between the drift layer and a base substrate. This high-donor-concentration layer is effective in that the layer makes it difficult for a depletion layer extending from an upper section of the drift layer towards the base substrate, to reach the base substrate under an off-state of the associated semiconductor device. In semiconductor substrates of such a structure as the above, unlike the present invention, the basal plane dislocation density propagating from the base substrate cannot be reduced. The present invention, however, can also be applied to those semiconductor substrates, in which case, the dislocation conversion layer can be provided between the drift layer and the high-donor-concentration layer or between the high-donor-concentration layer and the base substrate. Irrespective of whether the layer arrangement form is the former or the latter, the dislocation conversion layer, the drift layer, and the high-donor-concentration layer is formed using epitaxy. This means that the three layers can be stacked in required order by changing only the donor concentration, and hence that new defects do not occur in the drift layer.

As described above, when the present invention is used, the basal plane dislocation density in the drift layer can be reduced without causing new defects therein. In addition, an epitaxially-layered silicon carbide single-crystal wafer (also called “silicon carbide epiwafer”) that adopts the present invention can be used to form a device in exactly the same manner as that of a conventional silicon carbide epiwafer. That is to say, the present invention can be used to fabricate a device in the drift layer significantly reduced in basal plane dislocation density.

A p-n junction diode improved in reliability under an on-state and free from deterioration of characteristics under an off-state can be realized by providing a p-type layer that contains a p-type impurity, at an upper section of or inside the drift layer of the silicon carbide semiconductor substrate of the present invention, and further including an upper electrode provided in contact with the p-type layer, and a lower electrode provided in contact with the base substrate.

Additionally, a junction barrier Schottky rectifier (a Schottky barrier p-n junction combination) improved in reliability under an on-state and free from deterioration of characteristics under an off-state can be realized by providing a p-type layer that contains a p-type impurity, at an upper section of or inside the drift layer of the silicon carbide semiconductor substrate of the present invention, and further including an upper electrode provided in contact with the drift layer and the p-type layer, and a lower electrode provided in contact with the base substrate.

Furthermore, reliability of a MOSFET of a vertical structure can be improved by providing a p-type layer that contains a p-type impurity and functions as a channel, at an upper section of or inside the drift layer of the silicon carbide semiconductor substrate of the present invention, and further including a gate-insulating film provided on the surface of the p-type layer, a gate electrode provided on the gate-insulating film, an n-type source layer provided at an upper section or inside the p-type layer and having a higher donor concentration than the drift layer, a source electrode provided in contact with the source layer, and a drain electrode provided in contact with the base substrate.

According to one embodiment of the present invention, a silicon carbide semiconductor substrate that includes a semiconductor layer of a low basal-plane dislocation density can be provided in a base substrate formed of a silicon carbide semiconductor single crystal.

According to another embodiment of the present invention, the silicon carbide semiconductor substrate outlined above can be used to provide a drift layer of a low basal-plane dislocation density and form a device in the drift layer.

### BRIEF DESCRIPTION OF THE DRAWINGS

FIGS. 1A to 1C are sectional views that show manufacturing process steps relating to a silicon carbide semiconductor substrate according to a second embodiment of the present invention;

FIG. 2 shows a relationship between a flow rate of a nitrogen gas supplied during growth of a silicon carbide epitaxial layer in the present invention, and a donor concentration in the epitaxial layer;

FIG. 3 shows a relationship between the flow rate of the nitrogen gas supplied during the growth of the silicon carbide epitaxial layer in the present invention, and a basal plane dislocation density in the epitaxial layer;

FIGS. 4A and 4B are sectional views that show manufacturing process steps relating to a silicon carbide semiconductor substrate in a first comparative example according to the second embodiment of the present invention;

FIGS. 5A to 5D are sectional views that show manufacturing process steps relating to a silicon carbide semiconductor substrate according to a third embodiment of the present invention;

FIGS. 6A to 6C are sectional views that show manufacturing process steps relating to a silicon carbide semiconductor substrate in a second comparative example according to the third embodiment of the present invention;

FIGS. 7A to 7D are sectional views that show manufacturing process steps relating to a silicon carbide semiconductor substrate according to a fourth embodiment of the present invention;

FIGS. 8A to 8D are sectional views that show manufacturing process steps relating to a p-n junction diode according to a fifth embodiment of the present invention; and

FIGS. 9A to 9C are sectional views that show manufacturing process steps relating to a junction barrier Schottky rectifier according to a sixth embodiment of the present invention.

### DESCRIPTION OF THE PREFERRED EMBODIMENTS

Prior to describing more specific examples of the present invention, main embodiments of the invention are sorted out and enumerated below.

A first embodiment is a silicon carbide semiconductor substrate comprising a base substrate formed of a silicon carbide semiconductor single crystal, and a silicon carbide epitaxial growth layer formed on one surface of the base substrate, the epitaxial growth layer including: a first semiconductor layer with a desired donor concentration based on design specifications of the semiconductor device, the first semiconductor layer becoming a drift layer into which to build constituent elements of the semiconductor device; and a second semiconductor layer provided between the first semiconductor layer and the base substrate, and having a lower donor concentration than the first semiconductor layer.

A second embodiment is a silicon carbide semiconductor substrate comprising a base substrate formed of a silicon carbide semiconductor single crystal, and a silicon carbide epitaxial growth layer formed on one surface of the base substrate, the epitaxial growth layer including: a first semiconductor layer with a desired donor concentration based on design specifications of a semiconductor device, the first semiconductor layer becoming a drift layer into which to build constituent elements of the semiconductor device; a third semiconductor layer positioned at a lower section of the first semiconductor layer and having a higher donor concentration than the first semiconductor layer; and a second semiconductor layer provided between the first semiconductor layer and the high-donor-concentration third semiconductor layer, and having a lower donor concentration than the first semiconductor layer.

A third embodiment is a silicon carbide semiconductor substrate comprising a base substrate formed of a silicon carbide semiconductor single crystal, and a silicon carbide epitaxial growth layer formed on one surface of the base substrate, the epitaxial growth layer including: a first semiconductor layer with a desired donor concentration based on design specifications of a semiconductor device, the first semiconductor layer becoming a drift layer into which to build constituent elements of the semiconductor device; a third semiconductor layer positioned at a lower section of the first semiconductor layer and having a higher donor concentration than the first semiconductor layer; and a second semiconductor layer provided between the high-donor-concentration third semiconductor layer and the base substrate, and having a lower donor concentration than the first semiconductor layer.

In the above three embodiments, further embodiments are useful from a practical viewpoint.

In the first of the further embodiments mentioned above, the foregoing base substrate made of a silicon carbide semiconductor single crystal, on which an epitaxial growth layer are formed has a surface inclined by a maximum of 8 degrees from a {0001} crystal plane, and a donor concentration of the base substrate is 1×10¹⁸ cm⁻³ or more. In that case, the inclination angle of the above surface can range from nearly 3 to 8 degrees, and preferably, from 4 to 8 degrees. A currently, commercially available substrate formed of a silicon carbide single crystal suffices as the base substrate.

Impurities used as a donor in each semiconductor layer are preferably nitrogen.

A donor concentration of 1×10¹⁵ cm⁻³ or more, but up to 1×10¹⁶ cm⁻³, is generally used in the drift layer (the first semiconductor layer). Thickness of the drift layer is assigned according to particular functionality thereof. More specifically, the thickness ranges from about 5 to 30 micrometers.

As is evident from the foregoing fundamental experiments, setting the donor concentration in the second semiconductor layer to be lower than that of the first semiconductor layer correspondingly increases the effectiveness of the present invention. More practically, the difference in donor concentration from the first semiconductor layer is desirably at least ⅓, and preferably, at least about ½, of the donor concentration in the first semiconductor layer. A difference of at least one order of magnitude yields a remarkable effect. In general, the above difference in donor concentration ranges from 1×10¹⁴ cm⁻³ to 1×10¹⁵ cm⁻³. It suffices if the second semiconductor layer is nearly 10 nm or more in thickness. A thickness from 500 nm to about 1 micrometer would be a practical, maximum allowable value.

As described above, in the underlying technique of the present invention, the third semiconductor layer (high-donor-concentration layer) is used to make it difficult for a depletion layer extending from an upper section of the drift layer towards the base substrate, to reach the base substrate under an off-state of the semiconductor device. Thickness and impurity concentration of the third semiconductor layer are set in that perspective. A thickness from nearly 0.5 to 2-3 micrometers is most commonly used.

Furthermore, the present invention can use the above-described silicon carbide semiconductor substrates to provide the silicon carbide semiconductor devices represented by the following:

For example, a silicon carbide semiconductor device includes a p-type layer containing a p-type impurity and provided at the upper section of or inside the drift layer of one of the foregoing silicon carbide semiconductor substrates, an upper electrode provided in contact with the p-type layer, and a lower electrode provided in contact with the base substrate, and functions as a p-n junction. For example, another silicon carbide semiconductor device includes a p-type layer containing a p-type impurity and provided at the upper section of or inside the drift layer of one of the foregoing silicon carbide semiconductor substrates, an upper electrode provided in contact with the drift layer and the p-type layer, and a lower electrode provided in contact with the base substrate, and functions as a diode.

Embodiments of the present invention are next described. In the description below, the first to third semiconductor layers are referred to by using alternative names such as the drift layer, except in special cases.

### First Embodiment

The basic mode of the present invention that includes a silicon carbide semiconductor substrate having a semiconductor layer of a low basal-plane dislocation density above a base substrate formed of a silicon carbide semiconductor single crystal is used as a first embodiment of the invention to study growth conditions for obtaining a low-donor-concentration silicon carbide epitaxial layer to be used as a dislocation conversion layer.

First, the base substrate formed of a silicon carbide single-crystal wafer is prepared for use. The silicon carbide single-crystal wafer is 4H—SiC with a 50-mm diameter n-type (0001) plane inclined by 8 degrees in a direction of [11-20]. The growth uses the Si-plane side of the wafer provided with chemical-mechanical polishing (CMP) after being mechanically polished into a mirror-like surface. This silicon carbide single-crystal wafer has a donor concentration of 3×10¹⁸ cm⁻³.

After being RCA-cleaned, the base substrate is set up in a susceptor provided inside a reactor of a hot-wall-type CVD (Chemical Vapor Deposition) apparatus, and then an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. The retention is performed to remove damaged layers from the substrate surface by etching with the hydrogen.

After a susceptor temperature of 1,500° C. has been reached, the susceptor is retained at this temperature and a propane gas is supplied to the reactor at a flow rate of 0.6 sccm. This is followed by simultaneous supply of a monosilane gas and a nitrogen gas to the reactor at flow rates of 1.0 sccm and 1.0 sccm, respectively. Supply of the monosilane gas initiates the growth of a silicon carbide-nitrogen epitaxial layer. The flow rate of the nitrogen gas was varied to grow several kinds of epitaxial films.

After the above state has been maintained for 1 hour, supply of the monosilane gas and the nitrogen gas is stopped. Next, supply of the propane gas is stopped. After this, RF inductive heating is stopped and cooling in the hydrogen gas flow is started.

After the susceptor temperature has sufficiently decreased, supply of the hydrogen is stopped and after vacuum evacuation of the reactor interior, the substrate is removed from the susceptor.

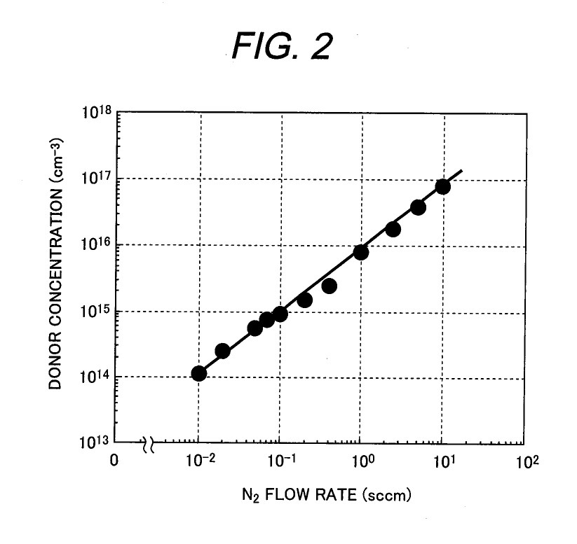

Donor concentrations in each epitaxial film that has grown were calculated from mercury-probed capacity-voltage measurement results. A relationship between the donor concentration and the flow rate of the nitrogen supplied during the growth is shown in FIG. 2. It was confirmed that the donor concentration in the epitaxial layer can be controlled in a range from 1×10¹⁴ cm⁻³ to 1×10¹⁷ cm⁻³, depending on the supply rate of the nitrogen gas. Film thicknesses of these epitaxial films were about 0.5 μm.

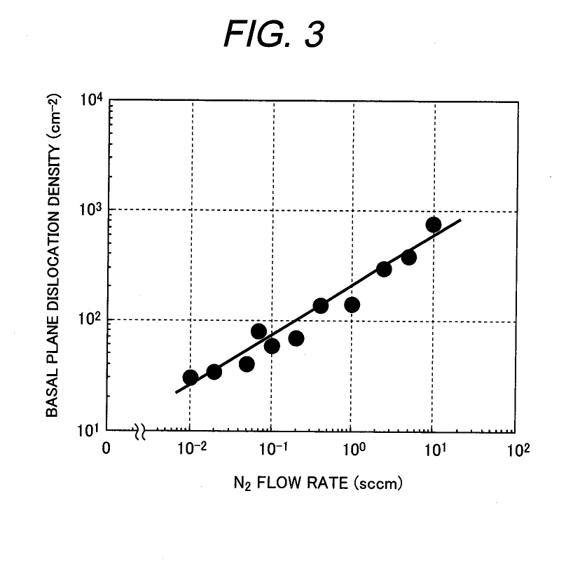

The epitaxially grown film is immersed together with the substrate in a 500° C.-fused potassium hydroxide solution for 5 minutes. Etch-pits due to the dislocations which have become exposed on the surface of the epitaxial layer are thus formed. Since etch-pits due to basal plane dislocations can be discriminated from those caused by other dislocations, the basal plane dislocation density can be calculated by counting the number of etch-pits by using an optical microscope. A relationship between the basal plane dislocation density and the flow rate of the nitrogen supplied during the growth of the epitaxial layer is shown in FIG. 3. It was confirmed that the basal plane dislocations in the epitaxial layer decrease with reductions in the supply rate of the nitrogen gas, that is, reductions in the donor concentration of the epitaxial layer.

### Second Embodiment

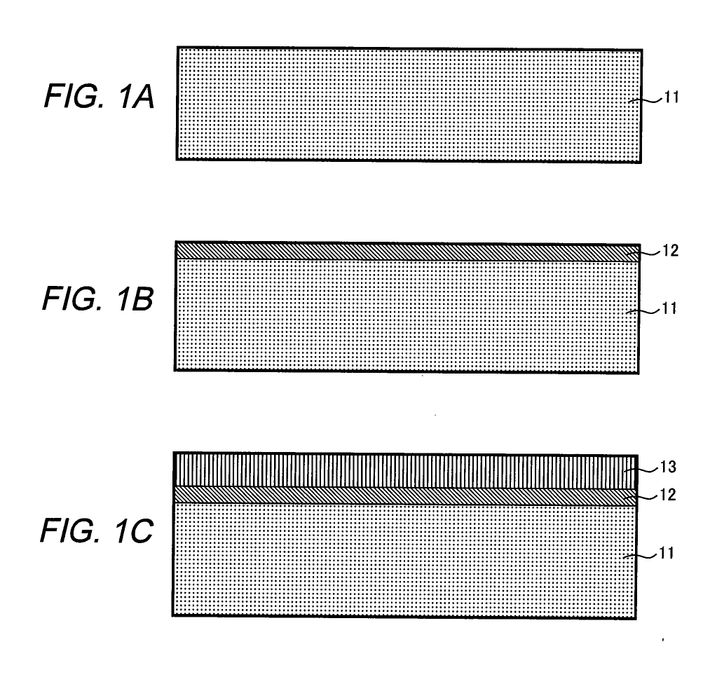

A method of manufacturing a silicon carbide semiconductor substrate usable for forming a semiconductor device will be described as a second embodiment of the present invention. The description is based on knowledge that was obtained from the foregoing fundamental experiments. FIGS. 1A to 1C are sectional views that show manufacturing process steps relating to the silicon carbide semiconductor substrate according to the present embodiment.

First, in the step shown in FIG. 1A, a base substrate 11 formed of a silicon carbide single-crystal wafer is prepared for use. The silicon carbide single-crystal wafer is 4H—SiC with a 50-mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of ×10¹⁸ cm⁻³.

Next, in the step shown in FIG. 1B, the base substrate 11 in FIG. 1A is RCA-cleaned, then the substrate 11 is set up in a susceptor provided inside a reactor of a hot-wall-type CVD apparatus, and an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 0.6 sccm. This is followed by simultaneous supply of a monosilane gas and a nitrogen gas to the reactor at flow rates of 1 sccm and 0.05 sccm, respectively. Supply of the monosilane gas initiates the growth of a silicon carbide-nitrogen epitaxial layer. This state is maintained for 12 minutes, whereby a dislocation conversion layer 12 about 0.1 μm thick is formed on the base substrate 11. As can be read from FIG. 2, the dislocation conversion layer 12 has a donor concentration of about 5×10¹⁴ cm⁻³.

Next after the formation of the dislocation conversion layer 12 in FIG. 1B, the flow rates of the monosilane, propane, and nitrogen gases are changed to 6 sccm, 2.4 sccm, and 0.2 sccm, respectively, in the step of FIG. 1C. This state is maintained for 120 minutes, whereby a drift layer 13 about 6 μm thick is formed on the dislocation conversion layer 12. According to preliminary studies that were conducted separately, a donor concentration in the epitaxial film formed under the above conditions was estimated at about 1×10¹⁶ cm⁻³, the value of which is about 20 times as great as the donor concentration of the dislocation conversion layer 12.

After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor interior, the substrate is removed from the susceptor.

The silicon carbide semiconductor substrate according to the present embodiment is formed through the above steps. Etch-pits are next formed on the thus-formed silicon carbide semiconductor substrate by using a fused potassium hydroxide solution, and a basal plane dislocation density of 60 cm⁻² is obtained. This value is essentially equal to the basal plane dislocation density estimated to be present in the dislocation conversion layer 12 formed in the step of FIG. 1B. Also, the basal plane dislocation density of 60 cm⁻² is estimated to be due to the fact that the basal plane dislocations reduced via the dislocation conversion layer 12 were almost propagated into the drift layer intact without subsequently increasing.

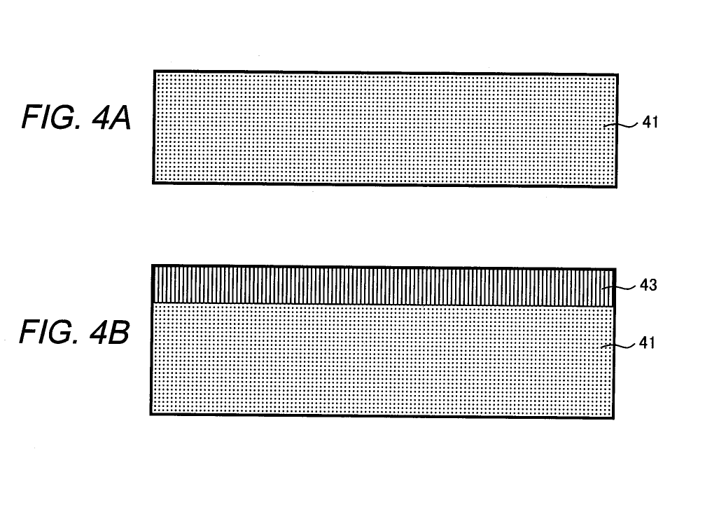

For the sake of comparison with the present embodiment, a drift layer was formed without the dislocation conversion layer 12 being provided. This silicon carbide semiconductor substrate is hereinafter defined as a first comparative example. FIGS. 4A and 4B are sectional views that show manufacturing process steps relating to the silicon carbide semiconductor substrate that is the first comparative example.

First, in the step shown in FIG. 4A, a base substrate 41 formed of a silicon carbide single-crystal wafer is prepared for use. The silicon carbide single-crystal wafer is 4H—SiC with a 50 mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of 3×10¹⁸ cm⁻³.

Next, in the step shown in FIG. 4B, the base substrate 41 in FIG. 4A is RCA-cleaned, then the substrate 41 is set up in a susceptor provided inside a reactor of a hot-wall-type CVD apparatus, and an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 2.4 sccm. This is followed by simultaneous supply of a monosilane gas and a nitrogen gas to the reactor at flow rates of 6 sccm and 0.2 sccm, respectively. Supply of the monosilane gas initiates the growth of a silicon carbide-nitrogen epitaxial layer. This state is maintained for 120 minutes, whereby the drift layer 43 about 6 μm thick is formed on the base substrate 41.

After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor interior, the substrate is removed from the susceptor. A donor concentration in this drift layer was measured to find that the concentration was 1×10¹⁶ cm⁻³ as pre-estimated.

The first comparative example of a silicon carbide semiconductor substrate according to the present embodiment is formed through the above steps. Etch-pits are next formed on the thus-formed silicon carbide semiconductor substrate by using a fused potassium hydroxide solution, and a basal plane dislocation density of 460 cm⁻² is derived.

As can be seen from the above, the basal plane dislocation density in the drift layer can be significantly reduced by providing the dislocation conversion layer 12 shown in FIG. 1.

The donor concentration of the drift layer 43 formed at the nitrogen flow rate of 0.2 sccm is 1×10¹⁶ cm⁻³, and the reason why this value increases above a value of 2×10¹⁵ cm⁻³ that can be read from FIG. 2 is that the flow rates and mixing ratio of the propane and monosilane gases differ from those of the epitaxial film associated with the data of FIG. 2.

### Third Embodiment

A method of manufacturing a silicon carbide semiconductor substrate usable for forming a device and different from the semiconductor substrate of the second embodiment will be described as a third embodiment of the present invention. The description is based on the knowledge that was obtained in the first embodiment.

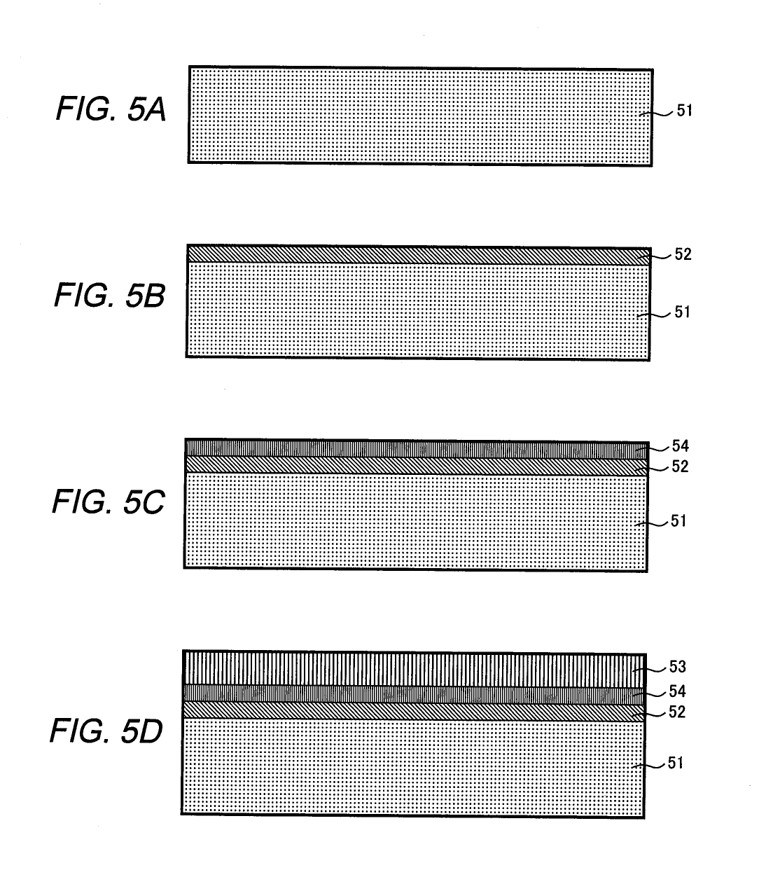

FIGS. 5A to 5D are sectional views that show manufacturing process steps relating to the silicon carbide semiconductor substrate according to the present embodiment.

First, in the step shown in FIG. 5A, a base substrate 51 formed of a silicon carbide single-crystal wafer is prepared for use. The silicon carbide single-crystal wafer is 4H—SiC with a 50-mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of 3×10¹⁸ cm⁻³.

Next, in the step shown in FIG. 5B, the base substrate 51 in FIG. 5A is RCA-cleaned, then the substrate 51 is set up in a susceptor provided inside a reactor of a hot-wall-type CVD apparatus, and an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 0.6 sccm. This is followed by simultaneous supply of a monosilane gas and a nitrogen gas to the reactor at flow rates of 1 sccm and 0.01 sccm, respectively. Supply of the monosilane gas initiates the growth of a silicon carbide-nitrogen epitaxial layer. This state is maintained for 12 minutes, whereby a dislocation conversion layer 52 about 0.1 μm thick is formed on the base substrate 51. It is estimated from FIG. 2 that the dislocation conversion layer 52 has a donor concentration of about 1×10¹⁴ cm⁻³.

Next after the formation of the dislocation conversion layer 52 in FIG. 5B, the flow rates of the monosilane, propane, and nitrogen gases are changed to 6.0 sccm, 1.8 sccm, and 5.0 sccm, respectively, in the step of FIG. 5C. This state is maintained for 20 minutes, whereby a high-donor-concentration layer 54 about 1.0 μm thick is formed on the dislocation conversion layer 52. According to preliminary studies that were conducted separately, the donor concentration in the epitaxial film formed under the above conditions was estimated at about 1×10¹⁸ cm⁻³.

The donor concentration in the high-donor-concentration layer 54 formed at the nitrogen flow rate of 5.0 sccm is 1×10¹⁸ cm⁻³, and the reason why this value increases above a value of 3×10¹⁶ cm⁻³ that can be read from FIG. 2 is that the flow rates and mixing ratio of the propane and monosilane gases differ from those of the epitaxial film associated with the data of FIG. 2.

Next after the formation of the high-donor-concentration layer 54 in FIG. 5C, the flow rates of the monosilane, propane, and nitrogen gases are changed to 12.0 sccm, 4.8 sccm, and 2.0 sccm, respectively, in the step of FIG. 5D. This state is maintained for 200 minutes, whereby a drift layer 53 about 20 μm thick is formed on the high-donor-concentration layer 54.

According to preliminary studies that were conducted separately, the donor concentration in the epitaxial film formed under the above conditions is estimated at about 2×10¹⁵ cm⁻³.

After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor interior, the substrate is removed from the susceptor.

The silicon carbide semiconductor substrate according to the present embodiment is formed through the above steps. Etch-pits are next formed on the thus-formed silicon carbide semiconductor substrate by using a fused potassium hydroxide solution, and a basal plane dislocation density of 27 cm⁻² is obtained. This value is essentially equal to the basal plane dislocation density estimated to be present in the dislocation conversion layer 52. Also, the basal plane dislocation density of 27 cm⁻² is estimated to be due to the fact that the basal plane dislocations reduced via the dislocation conversion layer were almost propagated into the drift layer intact without subsequently increasing.

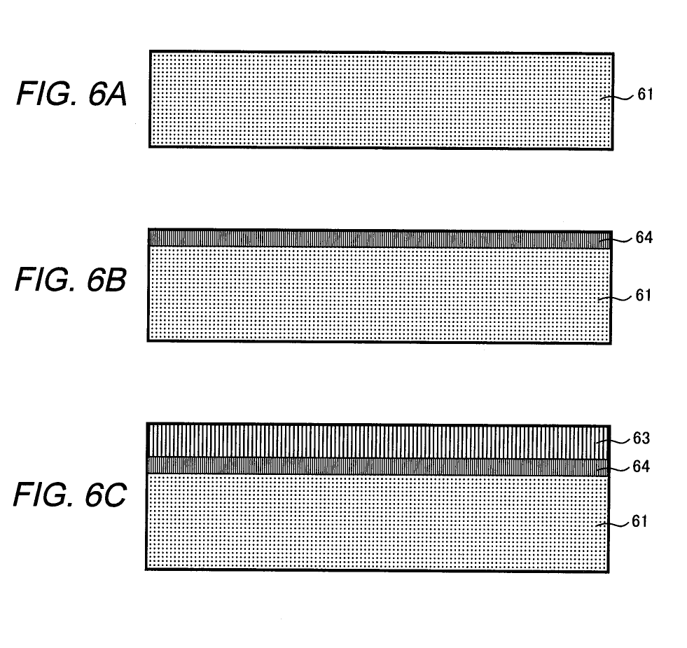

For the sake of comparison with the present embodiment, a high-donor-concentration layer and a drift layer were formed without the dislocation conversion layer 52 being provided. This silicon carbide semiconductor substrate is hereinafter defined as a second comparative example. FIGS. 6A to 6C are sectional views that show manufacturing process steps relating to the silicon carbide semiconductor substrate that is the second comparative example.

First, in the step shown in FIG. 6A, a base substrate 61 formed of a silicon carbide single-crystal wafer is prepared for use. The silicon carbide single-crystal wafer is 4H—SiC with a 50-mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of 3×10¹⁸ cm⁻³.

Next, in the step shown in FIG. 6B, the base substrate 61 in FIG. 6A is RCA-cleaned, then the substrate 61 is set up in a susceptor provided inside a reactor of a hot-wall-type CVD apparatus, and an internal pressure of the CVD reactor is reduced to a degree of vacuum below 3×10−5 Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 1.8 sccm. This is followed by simultaneous supply of a monosilane gas and a nitrogen gas to the reactor at flow rates of 6.0 sccm and 5.0 sccm, respectively. Supply of the monosilane gas initiates the growth of a silicon carbide-nitrogen epitaxial layer. This state is maintained for 20 minutes, whereby a high-donor-concentration layer 64 about 1.0 μm thick is formed on the base substrate 61. It is estimated from preliminary experiments that the donor concentration in the high-donor-concentration layer 64 is about 1×10¹⁸ cm⁻³.

Next after the formation of the high-donor-concentration layer 64 in FIG. 6B, the flow rates of the monosilane, propane, and nitrogen gases are changed to 12.0 sccm, 4.8 sccm, and 2.0 sccm, respectively, in the step of FIG. 6C. This state is maintained for 200 minutes, whereby a drift layer 63 about 20 μm thick is formed on the high-donor-concentration layer 64. After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor, the substrate is removed from the susceptor.

The second comparative example of a silicon carbide semiconductor substrate according to the present embodiment is formed through the above steps. Etch-pits are next formed on the thus-formed silicon carbide semiconductor substrate by using a fused potassium hydroxide solution, and a basal plane dislocation density of 870 cm⁻² is derived.

As described above, the present embodiment is equivalent to a configuration obtained by providing a dislocation conversion layer between the base substrate 61 and high-concentration layer 64 in the second comparative example. The basal plane dislocation density in the drift layer can therefore be significantly reduced by providing the dislocation conversion layer 52.

### Fourth Embodiment

A method of manufacturing a silicon carbide semiconductor substrate usable for a semiconductor device and different from the semiconductor substrates of the second and third embodiments will be described as a fourth embodiment of the present invention. The description is based on the knowledge that was obtained in the first embodiment.

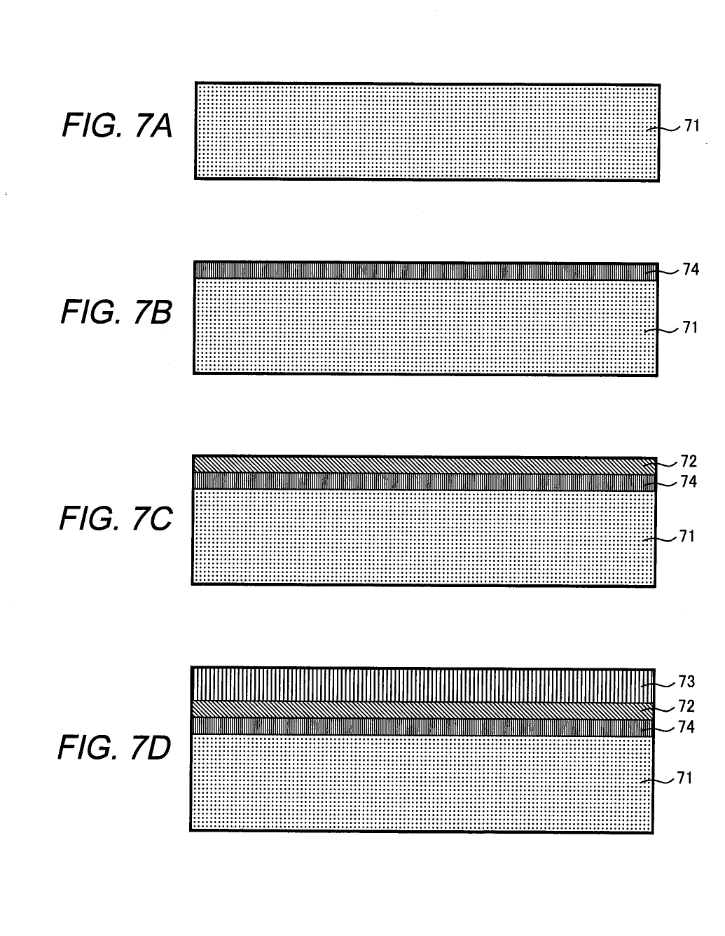

FIGS. 7A to 7D are sectional views that show manufacturing process steps relating to the silicon carbide semiconductor substrate according to the present embodiment.

First, in the step shown in FIG. 7A, a base substrate 71 formed of a silicon carbide single-crystal wafer is prepared for use. The silicon carbide single-crystal wafer is 4H—SiC with a 50-mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of 3×10¹⁸ cm⁻³.

Next, in the step shown in FIG. 7B, the base substrate 71 in FIG. 7A is RCA-cleaned, then the substrate 71 is set up in a susceptor provided inside a reactor of a hot-wall-type CVD apparatus, and an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 1.8 sccm. This is followed by simultaneous supply of a monosilane gas and a nitrogen gas to the reactor at flow rates of 6.0 sccm and 5.0 sccm, respectively. Supply of the monosilane gas initiates the growth of a silicon carbide-nitrogen epitaxial layer. This state is maintained for 20 minutes, whereby a high-donor-concentration layer 74 about 1.0 μm thick is formed on the base substrate 71. It is estimated from preliminary experiments that the high-donor-concentration layer 74 has a donor concentration of about 1×10¹⁷ cm⁻³.

Next after the formation of the high-donor-concentration layer 74 in FIG. 7B, the flow rates of the monosilane, propane, and nitrogen gases are changed to 1.00 sccm, 0.60 sccm, and 0.01 sccm, respectively, in the step of FIG. 7C. This state is maintained for 12 minutes, whereby a dislocation conversion layer 72 about 0.1 μm thick is formed on the high-donor-concentration layer 74. It is estimated from FIG. 2 that the dislocation conversion layer 72 has a donor concentration of about 1×10¹⁴ cm⁻³. Next after the formation of the dislocation conversion layer 72 in FIG. 7C, the flow rates of the monosilane, propane, and nitrogen gases are changed to 12.0 sccm, 4.8 sccm, and 2.0 sccm, respectively, in the step of FIG. 7D. This state is maintained for 200 minutes, whereby a drift layer 73 about 20 μm thick is formed on the dislocation conversion layer 72.

After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor, the substrate is removed from the susceptor.

The silicon carbide semiconductor substrate according to the present embodiment is formed through the above steps. Etch-pits are next formed on the thus-formed silicon carbide semiconductor substrate by using a fused potassium hydroxide solution, and a basal plane dislocation density of 40 cm⁻² is derived.

The present embodiment is equivalent to a configuration obtained by providing a dislocation conversion layer between the high-concentration layer 64 and drift layer 63 in the second comparative example. In that case, the basal plane dislocation density in the drift layer can also be significantly reduced by providing the dislocation conversion layer 72 of FIG. 7.

### Fifth Embodiment

A method of manufacturing a p-n junction diode which uses the silicon carbide semiconductor substrate obtained in the second embodiment will be described as a fifth embodiment of the present invention.

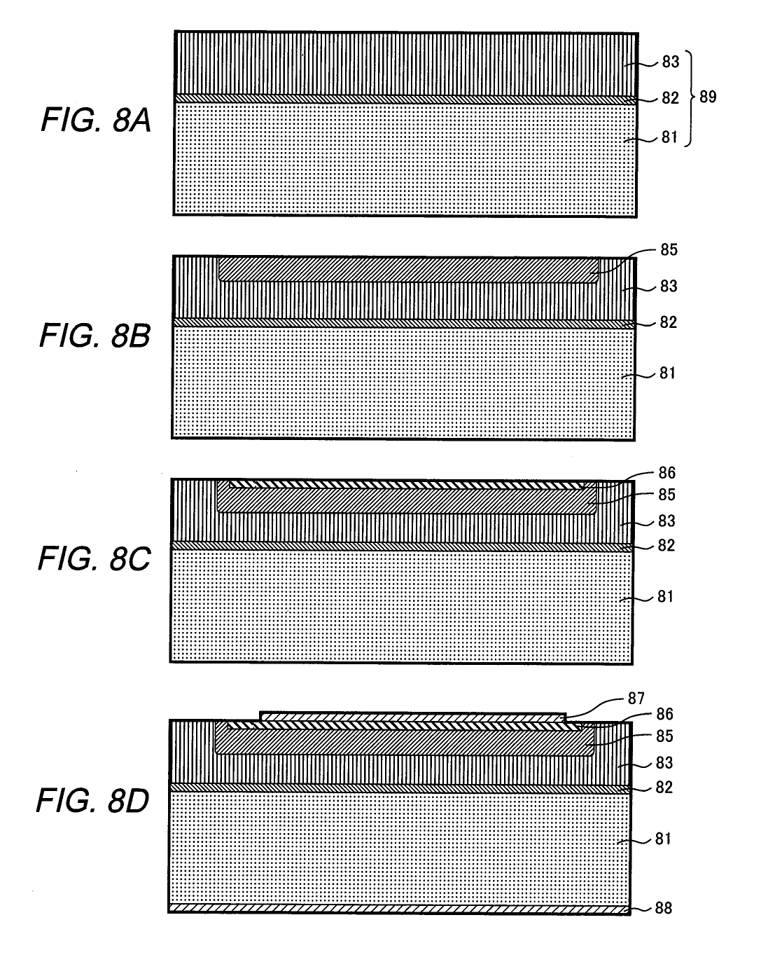

FIGS. 8A to 8D are sectional views that show manufacturing process steps relating to the p-n junction diode according to the present embodiment.

As shown in FIG. 8D, the p-n junction diode according to the present embodiment includes: a base substrate 81 formed of n-type 4H—SiC; a basal plane dislocation conversion layer 82 provided on a principal plane of the base substrate 81 and formed of a 0.1 μm thick silicon carbide epitaxial layer containing a small amount of nitrogen; a nitrogen-containing n-type drift layer 83 with a thickness of about 6 μm, provided on the basal plane dislocation conversion layer 82; a p-type doped layer 85 provided on a portion of the surface of the drift layer 83 and having a thickness of about 0.5 μm, inclusive of aluminum (Al); a high-concentration p-type layer 86 provided on the p-type doped layer 85 and having a thickness of about 0.1 μm, inclusive of Al; an upper electrode 87 formed by stacking nickel (Ni) and Al provided on the high-concentration p-type layer 86; and a lower electrode 88 formed of Ni provided on the reverse side of the base substrate 81.

The base substrate 81, the dislocation conversion layer 82, and the n-type drift layer 83 have donor concentrations of 3×10¹⁸ cm⁻³, 5×10¹⁴ cm⁻³, and 1×10¹⁶ cm⁻³, respectively. The p-type doped layer 85 and the high-concentration p-type layer 86 have acceptor concentrations of 2×10¹⁸ cm⁻³ and 5×10¹⁹ cm⁻³, respectively.

The p-n junction diode according to the present embodiment includes the dislocation conversion layer 82 between the base substrate 81 and the n-type drift layer 83. A basal plane dislocation density in the drift layer of this p-n junction diode is therefore low, compared with an associated value of a p-n junction diode based on the conventional technology. Accordingly, increases in on-resistance that occur when an on-state is sustained are expected to be suppressible.

Next, the method of manufacturing the p-n junction diode according to the present embodiment will be described.

First, in the step shown in FIG. 8A, the base substrate 81 formed of a silicon carbide single-crystal wafer is prepared for use. The silicon carbide single-crystal wafer is 4H—SiC with a 50 mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of 3×10¹⁸ cm⁻³.

Next after being RCA-cleaned, the base substrate 81 is set up in a susceptor provided inside a reactor of a hot-wall-type CVD apparatus and then an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 0.6 sccm. This is followed by simultaneous supply of a monosilane gas and a nitrogen gas to the reactor at flow rates of 1 sccm and 0.05 sccm, respectively. Supply of the monosilane gas initiates the growth of a silicon carbide-nitrogen epitaxial layer. This state is maintained for 12 minutes, whereby the dislocation conversion layer 82 about 0.1 μm thick is formed on the base substrate 81.

Next after the formation of the dislocation conversion layer 82, the flow rates of the monosilane, propane, and nitrogen gases are changed to 6.0 sccm, 2.4 sccm, and 0.2 sccm, respectively. This state is maintained for 120 minutes, whereby the drift layer 83 about 6 μm thick is formed on the dislocation conversion layer 82. After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor interior, the substrate is removed from the susceptor.

The silicon carbide semiconductor substrate 89 to be used in the present embodiment is formed through the above steps.

Next, in the step of FIG. 8B, aluminum (Al) ions are implanted into a portion of the surface of the drift layer 83, to thereby form the p-type doped layer 85.

The above is followed by, in the step of FIG. 8C, further implanting Al ions into a portion of the surface of the p-type doped layer 85 at a dose rate higher than for the drift layer 85, to thereby form the high-concentration p-type layer 86. After the p-type doped layer 85 and the high-concentration p-type layer 86 have thus been formed, activation annealing at 1,700° C. is conducted in an argon atmosphere.

After that, in the step of FIG. 8D, a stacked film of Ni and Al is deposited on an upper face of the high-concentration p-type layer 86, and a Ni film, on the reverse side of the base substrate 81, by using an electron beam evaporation apparatus. Heating to 1,000° C. under an argon atmosphere in a heater follows to form the upper electrode 87 and the lower electrode 88, as shown.

In this manner, the p-n junction diode according to the present embodiment is manufactured.

Increases in on-voltage were checked for by supplying a current of 50 A/cm² to the p-n junction diode of the present embodiment with this state maintained for 10 hours. An on-voltage increase of about 2 V was observed in a conventional p-n junction diode not having the dislocation conversion layer 82, whereas only about 0.1 V was observed in the present embodiment. This is considered to be due to the advantageous effect that the basal plane dislocations within the drift layer 83 were reduced by the dislocation conversion layer 82.

### Sixth Embodiment

A method of manufacturing a junction barrier Schottky rectifier (a Schottky barrier p-n junction combination) which uses the silicon carbide semiconductor substrate obtained in the third embodiment will be described as a sixth embodiment of the present invention.

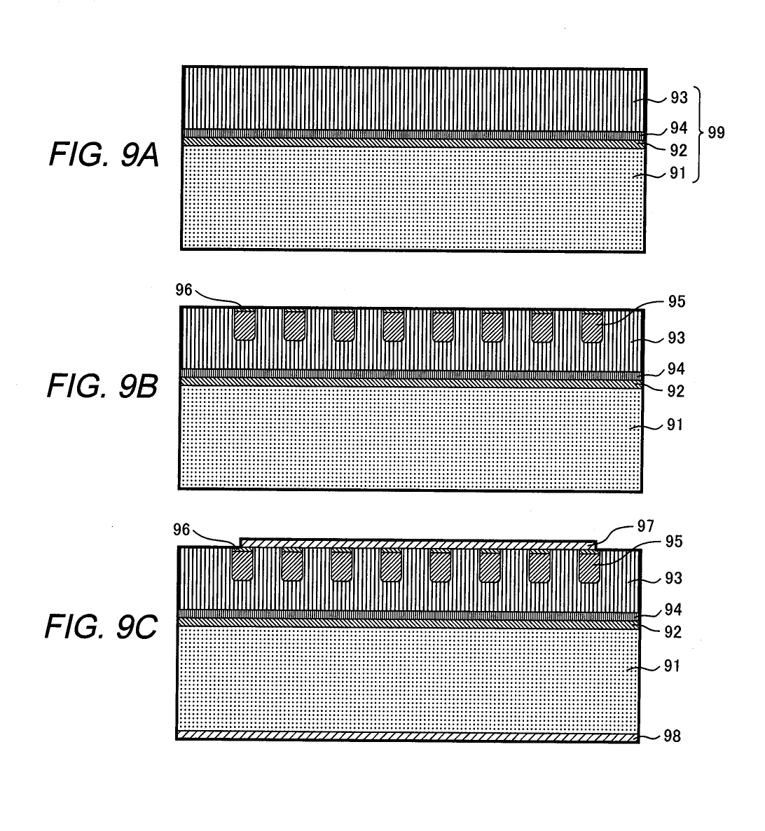

FIGS. 9A to 9C are sectional views that show manufacturing process steps relating to the junction barrier Schottky rectifier according to the present embodiment.

As shown in FIG. 9C, the junction barrier Schottky rectifier according to the present embodiment includes: a base substrate 91 formed of n-type 4H—SiC; a basal plane dislocation conversion layer 92 provided on a principal plane of the base substrate 91 and formed of a 0.1-μm thick silicon carbide epitaxial layer containing a small amount of nitrogen; a high-donor-concentration layer 94 provided on the basal plane dislocation conversion layer 92 and having a thickness of about 1.0 μm; a nitrogen-containing, n-type drift layer 93 with a thickness of about 20 μm, provided on the high-donor-concentration layer 94; a p-type doped layer 95 provided on a portion of the surface of the drift layer 93 and having a thickness of about 1 μm, inclusive of aluminum (Al); a high-concentration p-type layer 96 provided at an upper section of the p-type doped layer 95 and having a thickness of about 0.1 μm, inclusive of Al; an upper electrode 97 formed by stacking nickel (Ni) and Al provided in contact with both the drift layer 93 and the high-concentration p-type layer 96; and a lower electrode 98 formed of Ni provided on the reverse side of the base substrate 91.

The base substrate 91, the dislocation conversion layer 92, the high-donor-concentration layer 94, and the n-type drift layer 93 have donor concentrations of 3×10¹⁸ cm⁻³, 1×10¹⁴ cm⁻³, 1×10¹⁸ cm⁻³, and 2×10¹⁵ cm⁻³, respectively. The p-type doped layer 95 and the high-concentration p-type layer 96 have acceptor concentrations of 2×10¹⁸ cm⁻³ and 5×10¹⁹ cm⁻³, respectively.

The junction barrier Schottky rectifier according to the present embodiment includes the dislocation conversion layer 92 between the base substrate 91 and the high-donor-concentration layer 94. A basal plane dislocation density in the drift layer of this p-n junction diode is therefore low, compared with an associated value of a junction barrier Schottky rectifier based on the conventional technology. Accordingly, increases in on-resistance that occur when an on-state is sustained are expected to be suppressible.

Next, the method of manufacturing the junction barrier Schottky rectifier according to the present embodiment will be described.

First, in the step shown in FIG. 9A, the base substrate 91 formed of a silicon carbide single-crystal wafer is prepared for use. The silicon carbide single-crystal wafer is 4H—SiC with a 50 mm diameter n-type (0001) plane inclined by 8 degrees in the direction of [11-20]. Growth of epitaxial layers uses the silicon-plane side of the wafer provided with a CMP process after being mechanically polished into a mirror-like surface. This silicon carbide single-crystal wafer has a donor concentration of 3×10¹⁸ cm⁻³.

Next after being RCA-cleaned, the base substrate 91 is set up in a susceptor provided inside a reactor of a hot-wall-type CVD apparatus and then an internal pressure of the CVD reactor is reduced to a degree of vacuum below 3×10⁻⁵ Pa. After this, hydrogen is supplied as a carrier gas from a gas supply line at a flow rate of 10 slm to obtain a reactor internal pressure of 13.3 kPa. The susceptor is next heated using an RF inductive heating device with the flow rate of the hydrogen gas maintained.

After a susceptor temperature of 1,400° C. has been reached, the susceptor is retained in the hydrogen gas flow at this temperature for 10 minutes. Furthermore, after a susceptor temperature of 1,500° C. has been reached, the susceptor is retained at this temperature and a propane gas is supplied to the reactor at a flow rate of 0.6 sccm. This is followed by simultaneous supply of a monosilane gas and a nitrogen gas to the reactor at flow rates of 1 sccm and 0.01 sccm, respectively. Supply of the monosilane gas initiates the growth of a silicon carbide-nitrogen epitaxial layer. This state is maintained for 12 minutes, whereby the dislocation conversion layer 92 about 0.1 μm thick is formed on the base substrate 91.

Next after the dislocation conversion layer 92 has been formed, the flow rates of the monosilane, propane, and nitrogen gases are changed to 6.0 sccm, 1.8 sccm, and 5.0 sccm, respectively. This state is maintained for 20 minutes, whereby the high-donor-concentration layer 94 about 1.0 μm thick is formed on the dislocation conversion layer 92.

Next after the high-donor-concentration layer 94 has been formed, the flow rates of the monosilane, propane, and nitrogen gases are changed to 12.0 sccm, 4.8 sccm, and 2.0 sccm, respectively. This state is maintained for 200 minutes, whereby the drift layer 93 about 20 μm thick is formed on the high-donor-concentration layer 94.

After the drift layer has been formed, supply of the monosilane gas and the nitrogen gas is stopped. Next, supply of the propane gas is stopped. After this, RF inductive heating is also stopped and cooling in the hydrogen gas flow is started.

After the susceptor temperature has sufficiently decreased, supply of the hydrogen gas is stopped and after vacuum evacuation of the reactor interior, the substrate is removed from the susceptor.

A silicon carbide semiconductor substrate 99 to be used in the present embodiment is formed through the above steps.

Next, in the step of FIG. 9B, aluminum (Al) ions are implanted into a portion of the surface of the drift layer 93, to thereby form the p-type doped layer 95. This is followed by further implanting Al ions into the surface of the p-type doped layer 95 at a dose rate higher than the above, to thereby form the high-concentration p-type layer 96. After the p-type doped layer 95 and the high-concentration p-type layer 96 have thus been formed, activation annealing at 1,700° C. is conducted in an argon atmosphere.

After that, in the step of FIG. 9C, films of Ni and titanium (Ti) are deposited as a stacked film on the surface in contact with both the drift layer 93 and the high-concentration p-type layer 96, and a film of Ni, on the reverse side of the base substrate 91, by using an electron beam evaporation apparatus. Heating to 1,000° C. under an argon atmosphere in a heater follows to form the upper electrode 97 and the lower electrode 98, as shown.

In this manner, the junction barrier Schottky rectifier according to the present embodiment is manufactured.

Increases in on-voltage were checked for by supplying a current of 50 A/cm² to the junction barrier Schottky rectifier of the present embodiment with this state maintained for 10 hours. An on-voltage increase of about 3 V was observed in a conventional junction barrier Schottky rectifier not having the dislocation conversion layer 92, whereas only about 0.5 V was observed in the present embodiment. This is considered to be due to the advantageous effect that the basal plane dislocations within the drift layer 93 were reduced by the dislocation conversion layer 92.

11, 41, 51, 61, 71, 81, 91: Base substrate, 12, 52, 72, 82, 92: Dislocation conversion layer (second semiconductor layer), 13, 43, 53, 63, 73, 83, 93: Drift layer (first semiconductor layer), 54, 64, 74, 94: High-donor-concentration layer (third semiconductor layer), 85, 95: p-type doped layer, 86, 96: High-concentration p-type layer, 87, 97: Upper electrode, 88, 98: Lower electrode, 89, 99: Silicon carbide semiconductor substrate.

What is claimed is:

1. A silicon carbide semiconductor substrate, comprising:
a base substrate formed of a silicon carbide semiconductor single crystal; and
a silicon carbide epitaxial growth layer formed on one surface of the base substrate;
wherein the epitaxial growth layer includes:
a first semiconductor layer with a desired donor concentration, becoming a drift layer into which to build constituent elements of a semiconductor device; and
a second semiconductor layer provided between the first semiconductor layer and the base substrate, the second semiconductor layer having a lower donor concentration than the first semiconductor layer.

2. The silicon carbide semiconductor substrate according to claim 1, wherein:
the base substrate surface for forming the epitaxial growth layer is inclined by a maximum of 8 degrees from a {0001} crystal plane; and
the base substrate has a donor concentration of at least 1×10¹⁸ cm⁻³.

3. The silicon carbide semiconductor substrate according to claim 1, wherein an impurity used as the donor is nitrogen.

4. The silicon carbide semiconductor substrate according to claim 1, wherein a donor concentration in the second semiconductor layer is equal to or greater than 1×10¹⁴ cm⁻³, but up to 1×10¹⁵ cm⁻³.

5. The silicon carbide semiconductor substrate according to claim 1, further comprising:
a third semiconductor layer provided between the second semiconductor layer and the base substrate, the third semiconductor layer having a higher donor concentration than the first semiconductor layer.

6. The silicon carbide semiconductor substrate according to claim 5, wherein:
the base substrate surface for forming the epitaxial growth layer is inclined by a maximum of 8 degrees from a {0001} crystal plane; and
the base substrate has a donor concentration of at least 1×10¹⁸ cm⁻³.

7. The silicon carbide semiconductor substrate according to claim 5, wherein an impurity used as the donor is nitrogen.

8. The silicon carbide semiconductor substrate according to claim 5, wherein a donor concentration in the second semiconductor layer is equal to or greater than 1×10¹⁴ cm⁻³, but up to 1×10¹⁵ cm⁻³.

9. The silicon carbide semiconductor substrate according to claim 1, further comprising a third semiconductor layer provided between the first semiconductor layer and the second semiconductor layer, the third semiconductor layer having a higher donor concentration than the first semiconductor layer.

10. The silicon carbide semiconductor substrate according to claim 9, wherein:
the base substrate surface for forming the epitaxial growth layer is inclined by a maximum of 8 degrees from a {0001} crystal plane; and
the base substrate has a donor concentration of at least 1×10¹⁸ cm⁻³.

11. The silicon carbide semiconductor substrate according to claim 9, wherein an impurity used as the donor is nitrogen.

12. The silicon carbide semiconductor substrate according to claim 9, wherein a donor concentration in the second semiconductor layer is equal to or greater than 1×10¹⁴ cm⁻³, but up to 1×10¹⁵ cm⁻³.

13. A silicon carbide semiconductor device using a silicon carbide semiconductor substrate, the substrate comprising:
a base substrate formed of a silicon carbide semiconductor single crystal; and
a silicon carbide epitaxial growth layer formed on one surface of the base substrate;
wherein the epitaxial growth layer includes:
a first semiconductor layer with a desired donor concentration, becoming a drift layer into which to build constituent elements of the semiconductor device; and
a second semiconductor layer provided between the first semiconductor layer and the base substrate, the second semiconductor layer having a lower donor concentration than the first semiconductor layer, the epitaxial growth layer being adapted to further include: a p-type layer containing a p-type impurity, provided at an upper section of or inside the first semiconductor layer; an upper electrode provided in contact with the p-type layer; and a lower electrode provided in contact with the base substrate, and to function as a p-n junction diode.

14. A silicon carbide semiconductor device using a silicon carbide semiconductor substrate, the substrate comprising:
a base substrate formed of a silicon carbide semiconductor single crystal; and
a silicon carbide epitaxial growth layer formed on one surface of the base substrate;
wherein the epitaxial growth layer includes:
a first semiconductor layer with a desired donor concentration, becoming a drift layer into which to build constituent elements of the semiconductor device; and
a second semiconductor layer provided between the first semiconductor layer and the base substrate, the second semiconductor layer having a lower donor concentration than the first semiconductor layer, the epitaxial growth layer being adapted to further include: a p-type layer containing a p-type impurity, provided at an upper section of or inside the first semiconductor layer; an upper electrode provided in contact with the first semiconductor layer and the p-type layer; and a lower electrode provided in contact with the base substrate, and to function as a diode.

15. The silicon carbide semiconductor device according to claim 13, further comprising a third semiconductor layer provided between the second semiconductor layer and the base substrate, the third semiconductor layer having a higher donor concentration than the first semiconductor layer.

16. The silicon carbide semiconductor device according to claim 13, further comprising a third semiconductor layer having a higher donor concentration than the first semiconductor layer, the third semiconductor layer being provided between the first semiconductor layer and the second semiconductor substrate.

17. The silicon carbide semiconductor device according to claim 14, further comprising a third semiconductor layer having a higher donor concentration than the first semiconductor layer, the third semiconductor layer being provided between the second semiconductor layer and the base substrate.

18. The silicon carbide semiconductor device according to claim 14, further comprising a third semiconductor layer having a higher donor concentration than the first semiconductor layer, the third semiconductor layer being provided between the first semiconductor layer and the second semiconductor substrate.
